(19) United States
(12) Patent Application Publication
(10) Pub. No.: US 2013/0001618 A1
(43) Pub. Date: Jan. 3, 2013

(54) LIGHT-EMITTING ELEMENT MOUNTING SUBSTRATE AND LED PACKAGE

(75) Inventors: Noboru IMAI, Takahagi (JP); Fumiya ISAKA, Hitachi (JP); Tetsurou KITAMURA, Takahagi (JP); Masanori NEMOTO, Hitachi (JP); Minoru TANOI, Hitachi (JP)

(73) Assignee: HITACHI CABLE, LTD., Tokyo (JP)

(21) Appl. No.: 13/492,998

(22) Filed: Jun. 11, 2012

(30) Foreign Application Priority Data
Jun. 29, 2011 (JP) 2011-144544
Mar. 22, 2012 (JP) 2012-064700

(51) Int. Cl. H01L 33/60

(52) U.S. Cl. 257/98; 257/E33.072

(57) ABSTRACT

A light-emitting element mounting substrate includes an insulative substrate including a single-sided printed circuit board, a pair of wiring patterns formed on one surface of the substrate, the wiring patterns being separated with a first distance, a pair of through-holes penetrating through the substrate in a thickness direction, the through-holes being separated with a second distance, and a pair of filled portions including a metal filled in the pair of through-holes to contact the pair of wiring patterns and to be exposed on a surface of the substrate opposite to the one surface. Each of the pair of filled portions has a horizontal projected area of not less than 50% of an area of each the pair of wiring patterns.

The present application is based on Japanese patent application Nos. 2011-144544 and 2012-064700 filed on Jun. 29, 2011 and Mar. 22, 2012, respectively, the entire contents of which are incorporated herein by reference.

### BACKGROUND OF THE INVENTION

1. Field of the Invention

The invention relates to a light-emitting element mounting substrate and an LED package using the substrate.

2. Related Art

In recent years, display devices and illuminating devices using an LED (Light Emitting Diode) chip as a light-emitting element have attracted attention from the viewpoint of energy saving, which enhances competition of developing LED chips and products or technologies related thereto at a global level. As a symbolic example, even a rate per unit luminosity (yen/1 m) is well known as an index.

In such a circumstance, an LED chip which attracts attention from the viewpoint of luminous efficiency, besides a wire-bonding type LED chip having an electrode on a light emitting surface side, is a flip-chip type LED chip having an electrode provided on a back surface of an LED chip. Since heat dissipation of substrate, fineness of wiring pattern and flatness of substrate, etc., are required for a substrate for mounting the flip-chip type LED chip, ceramic substrates are currently often used.

However, since the ceramic substrates essentially need to be sintered in block with relatively small size (e.g., 50 mm square) and are less likely to be cheap even if mass-produced, a rate of sintering strain occurrence with respect to fineness level of the wiring pattern becomes more considerable as the wiring pattern becomes finer. In addition, since the thinness of the substrate has been also recently required, there is more probability that the substrate is broken by impact during handling.

Conventionally existing rigid substrates, tape substrates (TAB: Tape Automated Bonding), flexible substrates and metal-base substrates, etc., are considered to be used as alternative substrates. In such a case, a double-sided printed circuit board in which wirings formed on both surfaces of a substrate are electrically connected to each other by a through-via is generally adopted in order to achieve both of good heat dissipation and fineness of wiring pattern allowing flip-chip mounting (see, e.g., JP-A-2011-40488).

The light-emitting device disclosed in JP-A-2011-40488 is provided with a metal substrate having a conductive region and a non-conductive region, a pair of wiring patterns formed on the metal substrate via an insulation layer, an LED chip having two electrodes on a bottom surface and flip-chip mounted on the pair of wiring patterns, and a pair of through-vias for connecting the conductive region of the metal substrate to the two electrodes of the LED chip via the pair of wiring patterns.

### SUMMARY OF THE INVENTION

However, the double-sided printed circuit board in which very fine through-vias or wirings are formed in order to ensure heat dissipation is inevitably more expensive than the single-sided printed circuit board, which leads to loss of competitiveness based on the index defined by a rate per unit luminosity (yen/1 m). In addition, in the configuration to dissipate heat through a through-via having a smaller cross sectional area than a size of the LED chip, it is difficult to have a sufficient heat dissipation.

Accordingly, it is an object of the invention to provide a light-emitting element mounting substrate that allows good heat dissipation and flip-chip mounting even when being configured as a single-sided printed circuit board. Another object of the invention is to provide an LED package using the light-emitting element mounting substrate.

(1) According to one embodiment of the invention, a light-emitting element mounting substrate comprises:

an insulative substrate comprising a single-sided printed circuit board;

a pair of wiring patterns formed on one surface of the substrate, the wiring patterns being separated with a first distance;

a pair of through-holes penetrating through the substrate in a thickness direction, the through-holes being separated with a second distance; and

a pair of filled portions comprising a metal filled in the pair of through-holes to contact the pair of wiring patterns and to be exposed on a surface of the substrate opposite to the one surface,

wherein each of the pair of filled portions has a horizontal projected area of not less than 50% of an area of each the pair of wiring patterns.

In the above embodiment (1) of the invention, the following modifications and changes can be made.

(i) The insulative substrate has such flexibility that no crack occurs even when being bent at a radius of 50 mm.

(ii) The pair of wiring patterns each has an area of not less than 0.1 mm², wherein the first distance is formed on the one surface of the substrate so that the distance is not less than 1.5 times the thickness of wiring on a surface of the wiring pattern over a range of not less than 0.3 mm, and wherein the second distance is provided on the substrate so that the distance is not more than 0.2 mm on the one surface side of the substrate over a range of not less than 0.3 mm.

(iii) The pair of wiring patterns is formed of copper or copper alloy, and wherein the pair of filled portions comprises copper or copper alloy that is filled in the through-holes from the one surface side so as to be half the thickness of the substrate.

(iv) The pair of wiring patterns and the pair of filled portions both have a thermal conductivity of not less than 350 W/mk.

(v) The pair of wiring patterns each comprises a convex portion at a portion having the first distance, and wherein the pair of filled portions each comprise a convex portion at a portion having the second distance that is substantially the same position as the convex portion of the pair of wiring patterns.

(vi) The one surface side of the substrate including the pair of wiring patterns comprises a reflective layer that has an initial reflectance of not less than 80% within a wavelength range of 450 to 700 nm in measurement by a spectrophotometer using white color of barium sulfate (BaSO4) as a criterion.

(vii) The side opposite to the one surface of the substrate comprises a solder resist layer.

(2) According to another embodiment of the invention, an LED package comprises:

an LED chip as the light-emitting element mounted on the pair of wiring patterns of the light-emitting element mounting substrate according to claim 1 in a bridging manner or mounted on an upper surface of one of the wiring patterns, the LED chip being electrically connected to the wiring pattern(s); and

a sealing resin that seals the LED chip.

Points of the Invention

According to one embodiment of the invention, a light-emitting element mounting substrate is constructed such that in a single-sided printed circuit board, a pair of wiring patterns are formed on a surface of a resin film to have a distance as small as possible, and metal filled portions are formed in through-holes provided at positions corresponding the wiring patterns so as to penetrate through the resin film to contact the wiring patterns and be exposed on a back surface of the resin film. Therefore, the substrate can be used for the flip-chip mounting while having the good heat dissipation.

### BRIEF DESCRIPTION OF THE DRAWINGS

Next, the present invention will be explained in more detail in conjunction with appended drawings, wherein:

FIG. 1A is a cross sectional view showing an LED package in a first embodiment of the present invention and FIG. 1B is a plan view showing the LED package of FIG. 1A without sealing resin and reflective layer;

FIG. 2 is a plan view when manufacturing the LED package shown in FIG. 1A by TAB (Tape Automated Bonding);

FIGS. 3A to 3E are cross sectional views of an example of a method of manufacturing a light-emitting element mounting substrate, wherein a unit pattern is shown;

FIG. 4 is a plan view showing an LED package in a second embodiment of the invention;

FIG. 5 is a plan view showing an LED package in a third embodiment of the invention;

FIG. 6 is a plan view showing an LED package in a fourth embodiment of the invention;

FIG. 7A is a cross sectional view showing an LED package in a fifth embodiment of the invention and FIG. 7B is a plan view showing the LED package of FIG. 7A without sealing resin and reflective layer;

FIG. 8A is a cross sectional view showing an LED package in a sixth embodiment of the invention and FIG. 8B is a plan view showing the LED package of FIG. 8A without sealing resin and reflective layer;

FIG. 9A is a cross sectional view showing an LED package in a seventh embodiment of the invention and FIG. 9B is a plan view showing the LED package of FIG. 9A without sealing resin and reflective layer;

FIG. 10 is a cross sectional view showing an LED package in an eighth embodiment of the invention;

FIG. 11A is a cross sectional view showing an LED package in a ninth embodiment of the invention and FIG. 11B is a plan view showing the LED package of FIG. 11A without sealing resin and reflective layer; and

FIG. 12 is a cross sectional view showing an LED package in a tenth embodiment of the invention.

### DESCRIPTION OF THE PREFERRED EMBODIMENTS

Embodiments of the invention will be described below in reference to the drawings. It should be noted that, constituent elements having substantially the same function are denoted by the same reference numerals in each drawing and the overlapped explanation will be omitted.

### SUMMARY OF EMBODIMENTS

A light-emitting element mounting substrate in the embodiments is comprised of an insulative substrate comprising a single-sided printed circuit board, a pair of wiring patterns formed on one surface of the substrate so that the wiring patterns are separated with a first distance, a pair of through-holes formed to penetrate through the substrate in a thickness direction so that the through-holes are separated with a second distance and a pair of filled portions formed of a metal filled in the pair of through-holes to contact the pair of wiring patterns and to be exposed on a surface of the substrate opposite to the one surface, wherein each of the paired filled portions has a horizontal projected area of not less than 50% of an area of each of the paired wiring patterns.

A mounting region for mounting a light-emitting element is present in the wiring pattern. Here, the “mounting region” means a region generally in a rectangular shape in which a light-emitting element will be mounted. The mounting region is substantially equal to an area of the light-emitting element when mounting one light-emitting element and, when mounting plural light-emitting elements, it means a region surrounding plural light-emitting elements or plural regions corresponding to individual light-emitting elements. In addition, the “mounting region” may be present on the pair of wiring patterns in a bridging manner or may be present on one of the paired wiring patterns.

The filled portion is formed to have an area larger than that of the mounting region as well as not less than 50% of the area of the wiring pattern, and heat dissipation of the filled portion is thereby enhanced.

### First Embodiment

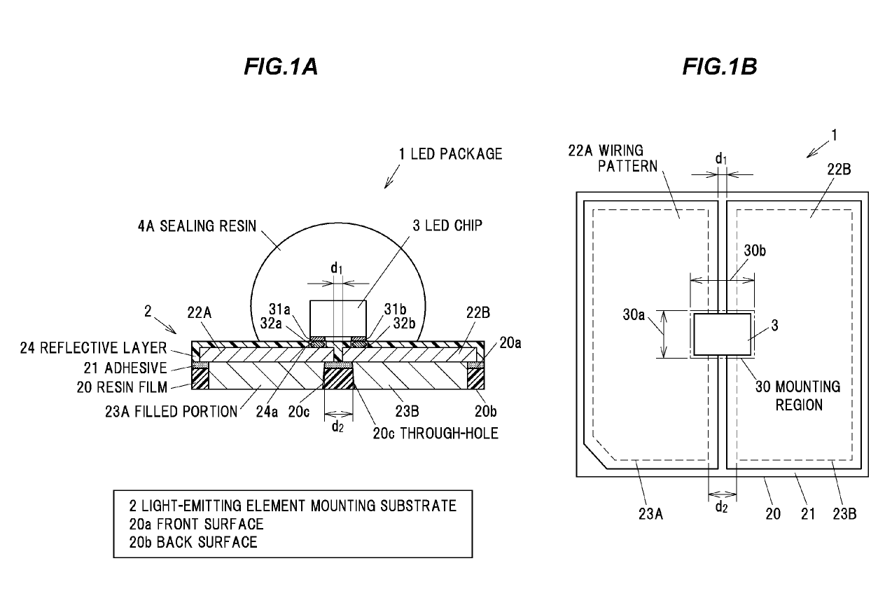

FIG. 1A is a cross sectional view showing an LED package in a first embodiment of the invention and FIG. 1B is a plan view showing the LED package of FIG. 1A without sealing resin and reflective layer.

An LED package 1 as an example of a light-emitting device is configured such that a flip-chip type LED chip 3 having electrodes 31a and 31b on a bottom surface thereof is flip-chip mounted as a light-emitting element on a light-emitting element mounting substrate 2 in a mounting region 30 of a pair of wiring patterns 22A and 22B using bumps 32a and 32b for connection, and the LED chip 3 is then sealed with a sealing resin 4A.

The light-emitting element mounting substrate 2 is a so-called single-sided printed circuit board having a wiring on one surface of a substrate, and is provided with a pair of wiring patterns 22A and 22B formed on a front surface 20a as one surface of a resin film 20 via an adhesive 21 and having a mounting region 30 for mounting a LED chip 3, a pair of filled portions 23A and 23B formed of a metal filled in a pair of through-holes 20c penetrating through the resin film 20 in a thickness direction so as to be in contact with the pair of wiring patterns 22A and 22B and so as to be exposed on a back surface 20b as a surface of the resin film 20 opposite to the one surface, and a reflective layer 24 formed on the front surface 20a side of the resin film 20 so as to cover the pair of wiring patterns 22A and 22B to reflect light from the LED chip 3.

Next, each component of the LED package 1 will be described.

Resin Film

The resin film 20 preferably has insulating properties and such flexibility (plasticity) that cracks do not occur even when being bent at a radius of 50 mm. As the resin film 20, it is possible to use a film formed of, e.g., polyimide, polyamide-imide, polyethylene naphthalate, epoxy or aramid, etc.

Wiring Pattern

The pair of wiring patterns 22A and 22B are separated from each other to have a first distance d1 (e.g., 0.04 mm) therebetween, which is present in the range of not less than a length (e.g., 0.3 mm) of a side 30a of the mounting region 30 in a predetermined direction of the mounting region 30, and is not more than a length of another side 30b of the mounting region 30 in a direction orthogonal to the predetermined direction. It is desirable that the wiring pattern be present in not less than 50% of an upper surface area of a semiconductor package. An exposed region of the resin film 20 which has lower reflection efficiency can be reduced by increasing a ratio of the wiring pattern area, which allows reflectance of the package to be improved as compared to a conventional package.

It should be noted that, it is desirable that the first distance d1 be set to a minimum value which allows formation by, e.g., photolithography technique and etching process. In detail, 30 μm to 100 μm is preferable.

In addition, the first distance d1 between the wiring patterns 22A and 22B may be determined to be d1≦(t+10 μm), where t is a thickness of the wiring patterns 22A and 22B. The preferred thickness t of the wiring patterns 22A and 22B is not less than 30 μm.

It is preferable that the wiring patterns 22A and 22B have a thermal conductivity of not less than 350 W/mk. Copper (pure copper) or copper alloy, etc., can be used as a material of such wiring patterns 22A and 22B. It is possible to realize 396 W/mk by using copper as a material of the wiring patterns 22A and 22B. Although the shape of the wiring patterns 22A and 22B is rectangular in the first embodiment, it is not limited thereto. It may be a polygon of five sides or more or a shape including curves or arcs, etc.

Filled Portion

The pair of wiring patterns 22A and 22B have a second distance d2 not more than a length (e.g., 0.3 mm) of the side 30b of the mounting region 30 in a predetermined direction of the mounting region 30 in the range of not less than a length (e.g., 0.3 mm) of the side 30a of the mounting region 30 in a direction orthogonal to the predetermined direction. It is preferable that the second distance d2 be not more than 0.2 mm. In addition, the pair of the filled portions 23A and 23B should each have an area which is larger than the area of the mounting region 30 and is not less than 50%, preferably not less than 75%, of the area of each of the wiring patterns 22A and 22B when viewed from the front surface 20a side of the resin film 20. The filled portions 23A and 23B may respectively have the areas larger than the areas of the wiring patterns 22A and 22B. In the first embodiment, the filled portions 23A and 23B have areas of about 80% of those of the wiring patterns 22A and 22B.

In the LED package, the filled portions are arranged under the mounted LED chip. Accordingly, the shortest heat conduction path is formed downwardly under the LED chip and it is thus possible to improve heat dissipation.

Although the filled portion is formed in a similar shape to the wiring pattern in the first embodiment, it is not limited thereto.

The through-holes 20c penetrating through the resin film 20 in the thickness direction are filled to half or more of the thickness of the resin film 20, thereby forming the filled portions 23A and 23B. In the first embodiment, the filled portions 23A and 23B are filled in substantially the whole through-holes 20c.

It is preferable that the filled portions 23A and 23B have a thermal conductivity of not less than 350 W/mk in the same manner as the wiring patterns 22A and 22B. Copper (pure copper) or copper alloy, etc., can be used as a material of such filled portions 23A and 23B. It is possible to realize 396 W/mk by using pure copper as a material of the wiring patterns 22A and 22B.

Reflective Layer

It is preferable that the reflective layer 24 have an initial total reflectance of not less than 80% within a wavelength range of 450 to 700 nm in measurement by a spectrophotometer using white color of barium sulfate (BaSO₄) as a criterion. A white film or resist may be use as such a material. Alternatively, silver plating may be applied to the wiring patterns 22A and 22B so as to serve as a reflective layer.

LED Chip

The LED chip 3 has a size of, e.g., 0.3 to 1.0 mm square and is provided with at least a pair of electrodes 31a and 31b made of aluminum, etc., on the bottom surface thereof and the bumps 32a and 32b made of gold, etc., formed on the electrodes 31a and 31b. The LED chip may be a wire-bonding type LED chip, which is connected by wires, having an electrode on each of bottom and upper surfaces or having not less than two electrodes on an upper surface, or may be a combination thereof.

Sealing Resin

Although the sealing resin 4A has a spherical surface or a curved surface in the first embodiment in order to impart directionality to light emitted from the LED chip 3, it is not limited thereto. In addition, it is possible to use resins such as silicone resin as a material of the sealing resin 4A.

Significance of Numerical Limitation

Next, the significance of the numerical limitation for each component will be described.

Flexibility of Resin Film

The following is the reason why the resin film 20 is formed so that cracks do not occur even when being bent at a radius R of 50 mm. In general, a roll-to-roll method is effective for efficiently performing a large volume of liquid treatment such as etching. However, when the resin film 20 is straightly fed to take enough processing time (length or processing) in the roll-to roll method, problems arise such that a feeding speed is too slow or manufacturing equipment is too long. In addition, an accumulation mechanism is required for replacing or joining the rolled resin film 20 while operating the manufacturing equipment. A method of solving such problems is generally to vertically feed a workpiece in a zigzag manner using, e.g., a fixed roller or a movable roller having the radius R of not less than 100 mm. This is why using the resin film 20 in which cracks do not occur even when being bent at the radius R of 50 mm.

Thickness of Wiring Pattern

The following is the reason why the wiring patterns 22A and 22B have a thickness of not less than 30 μm. When a copper foil is used as a material of the wiring patterns 22A and 22B, a copper foil is commercially available in units of 18 μm, 35 μm, 70 μm and 105 μm. Since the experience shows that a 18 μm-thick copper foil is often insufficient in heat conduction capacity in a horizontal direction, a copper foil having a thickness of not less than 35 μm is often used for the manufacturing. The thicknesses of the wiring patterns 22A and 22B are determined to be not less than 30 μm for the reason that the thickness of not less than 30 μm is ensured even if thinned by chemically polishing, etc., a surface thereof.

First Distance d1 Between Wiring Patterns

In the current etching technique, when a copper foil is used as a general material of the wiring patterns 22A and 22B, lines and spaces with a width equivalent to the thickness of the copper foil is the limit of fineness to be formed. Therefore, the first distance d1 between the wiring patterns 22A and 22B is determined to be the thickness of the copper foil+10 μm so as to allow some tolerance.

Thickness of Filled Portion

While the thicker filled portions 23A and 23B absorb more heat, have more heat dissipation area and are also more likely to come into contact with solder paste printed on a mounting board, thickening the filled portions 23A and 23B is disadvantageous in cost. Since the thickness of the resin film 20 is generally about 50 μm and the experience shows that about 25 μm which is 50% thereof is required, the thicknesses of the filled portions 23A and 23B are determined to be not less than half the thickness of the resin film 20.

Second Distance d2 Between Filled Portions

The smaller the second distance d2 between the filled portions 23A and 23B is, the better it is. However, the experience shows that the limit of width is about 0.15 mm to stably punch out, e.g., a 50 μm-thick polyimide as a material of the resin film 20 and the second distance d2 between the filled portions 23A and 23B is thus determined to be not more than 0.20 mm.

Method of Manufacturing LED Package

Next, an example of a method of manufacturing the LED package 1 shown in FIG. 1A will be described.

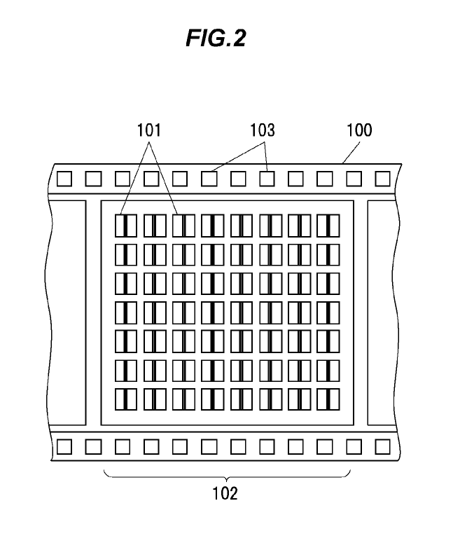

FIG. 2 is a plan view showing an appearance when manufacturing the LED package shown in FIG. 1A using a tape substrate (TAB: Tape Automated Bonding). It is possible to manufacture the LED package 1 using a tape substrate 100. Alternatively, the LED package 1 may be manufactured by other manufacturing methods using a rigid substrate or a flexible substrate, etc. In the tape substrate 100, plural blocks 102 each of which is a group of unit patterns 101 each for forming one LED package 1 are formed in a longitudinal direction, and sprocket holes 103 are formed on both sides of each block 102 at equal intervals.

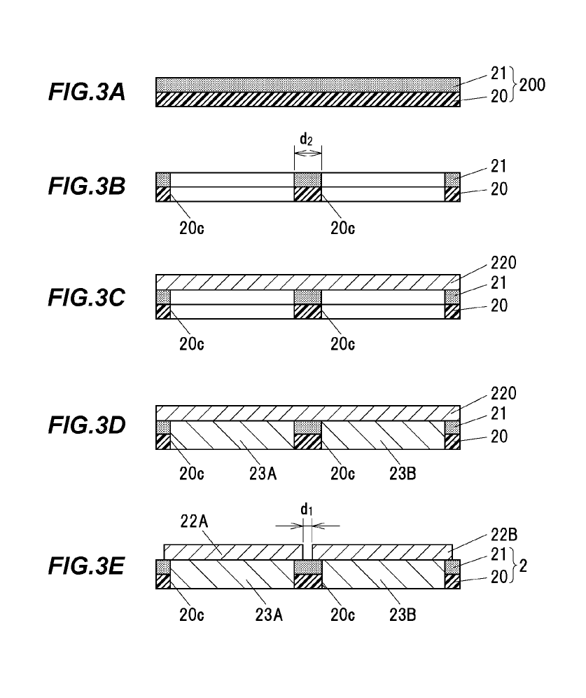

FIGS. 3A to 3E are cross sectional views of an example of a method of manufacturing the light-emitting element mounting substrate 2 shown in FIG. 1A, wherein one unit pattern 101 is shown.

(1) Preparation of Electrical Insulating Material

Firstly, an electrical insulating material 200 composed of the adhesive 21 and the resin film 20 is prepared as shown in FIG. 3A. The electrical insulating material 200 is commercially available (from Tomoegawa Co., Ltd., Toray Industries, Inc. and Arisawa Manufacturing Co., Ltd., etc.), and the adhesive 21 is protected by a cover film (not shown). When obtaining the electrical insulating material 200 not by purchase but by personally making, it is possible to make by laminating an epoxy-based thermosetting adhesive sheet on a film as the resin film 20 made of any resin of, e.g., polyimide, polyamide-imide, polyethylene naphthalate, epoxy or aramid. The electrical insulating material 200 in a rolled form is preferred to feed in a production line of TBA, and it may be laminated after being preliminary slit into a desired width or it may be slit into a desired width after laminating on a wide width (not shown).

(2) Formation of Through-Hole for Filled Portion

Next, the through-holes 20c for the filled portions 23A and 23B are punched in the electrical insulating material 200 by a punch die as shown in FIG. 3B. This process requires a rigid and highly accurate punch die since it is necessary to form the second distance d2 between the filled portions 23A and 23B to be not more than 0.20 mm over the length of not less than 0.30 mm. In detail, it is necessary to take a measure so that a die and a stripper of a movable stripper-type die are processed together by a wire electric discharge machine or a punch, a die and a stripper are processed with not more than ±0.002 mm of main machining accuracy to fine-adjust each clearance between the punch, the die and the stripper. In addition, the sprocket holes 103 or alignment holes (not shown) may be formed, if necessary, at the time of processing the through-holes 20c.

(3) Formation of Copper Foil

Next, a copper foil 220 is laminated as shown in FIG. 3C. If the copper foil 220 is selected from electrolytic foils or rolled foils having a thickness of about 35 to 105 μm in which surface roughness of a back surface is about not more than 3 μm in an arithmetic mean roughness Ra, it is relatively easy to form the first distance d1 (not more than the thickness of copper foil+10 μm) in the posterior etching process. Although it is preferable to use a roll laminator in a normal or reduced pressure environment for lamination, a diaphragm, plate-press or steel belt type laminator may be used. Conditions for lamination can be selected based on reference conditions given by adhesive manufacturers. For many of thermosetting adhesives, post curing is generally carried out at a high temperature of, e.g., not less than 150° C. after completing the lamination. This is also determined based on the reference conditions of the adhesive manufacturers.

(4) Embedding of Filled Portion

Next, as shown in FIG. 3D, electrolytic copper plating is embedded in the through-holes 20c, thereby forming the filled portions 23A and 23B. The embedding plating method is disclosed in JP-A 2003-124264, etc. In detail, copper plating is applied after masking a copper foil surface by a masking tape for plating. The front ends of the filled portions 23A and 23B can be formed to be convex, concave or flat by changing a type or plating conditions of a copper plating solution. In addition, the thickness of the filled portions 23A and 23B can be also adjusted by the plating conditions (mainly, plating time). Since the information about the copper plating solution and how to use can be easily obtained from manufacturers who sell copper plating solutions (Ebara-Udylite Co., Ltd. and Atotech Japan K.K., etc.), the detailed explanation will be omitted.

(5) Patterning of Copper Foil

Next, as shown in FIG. 3E, the copper coil 220 is patterned, thereby forming the wiring patterns 22A and 22B. Since photolithography is used for patterning, the wiring patterns 22A and 22B are formed through a series of processes, which are application of a resist to the copper foil 220, exposure to light, development and etching, and removal of the resist after etching, even though it is not illustrated.

When patterning the copper foil 220, a dry film may be used instead of the resist. In addition, it is desirable that the filled portions 23A and 23B be protected from chemical solution such as etching solution by sticking a masking tape or applying a back coating material to the surface of the embedded plating. A cross section of the pattern is spread downward when etching using only a general ferric chloride-based or cupric chloride-based etching solution, and the spread portions of the wiring patterns 22A and 22B are thus connected when the first distance d1 (not more than the thickness of the wiring patterns 22A and 22B+10 μm) is formed on the surface of the pattern. Accordingly, while protecting a sidewall of the copper foil 220 from the etching solution at the time of etching, it is necessary to select an etching solution of a type to etch in a plate thickness direction and to optimize a spray pattern, etc., of the etching solution. For example, ADEKA Corporation manufactures this type of etching solution. Meanwhile, when the distance d1 between the wiring patterns 22A and 22B cannot be reduced to a desired value by etching, copper plating can be applied to the formed wiring patterns 22A and 22B to increase the thickness and width thereof by the thickness of the copper plating, thereby reducing the distance d1 between the wiring patterns 22A and 22B.

(6) Plating Process

Next, the masking tape on the embedding plating side is removed and plating containing any metal of gold, silver, palladium, nickel, tin or copper is applied to the surfaces of the wiring patterns 22A, 22B and the filled portions 23A, 23B, even though it is not illustrated. Plural types of plural layers may be formed. Although electroless plating which does not require an electric supply line for plating is desirable as a plating method, electrolytic plating may be used. At this time, different types of plating may be applied while alternately masking the patterned surface of the copper foil and the embedding plating surface side. Alternatively, the patterned surface of the copper foil may be plated after covering a portion not requiring the plating by a resist or a cover lay in order to reduce a plating area.

The tape substrate 100 as shown in FIG. 2 can be formed by the above processes and the light-emitting element mounting substrate 2 is finished in a rolled form.

(7) Cutting of Tape Substrate and Mounting of LED Chip

Next, the finished tape substrate 100 is cut into a desired length per block 102 and the LED chip 3 is mounted on the mounting region 30 using a mounter. The most suitable mounter should be selected depending on a material (gold or solder) of the bumps 32a and 32b of the LED chip 3. In this regard, it is possible to mount a wire-bonding type LED chip in the same manner. The manufacture of the mounter may be, e.g., Juki Corporation, Panasonic Factory Solutions Co., Ltd., Hitachi High-Tech Instruments Co., Ltd. and Shinkawa Ltd., etc.

(8) Formation of Sealing Resin

Then, after, if necessary, plasma cleaning under atmospheric pressure or underfilling of the LED chip 3, the LED chip 3 is sealed (compression molded) with, e.g., a silicone resin as the sealing resin 4A by a compression molding apparatus and a mold. A phosphor may be mixed to the sealing resin 4A, or sealing may be carried out after potting sealing of a resin with a phosphor preliminarily mixed.

(9) Singulation of LED Package

Singulation (division) into each LED package 1 (one unit) is carried out. In this case, although dicing which is a cutting method using a grindstone is generally carried out, it is also possible to push-cut by, e.g., a blade called Thomson blade. The LED package 1 can be finished as described above.

Operation of the LED Package

Next, an operation of the LED package 1 will be described. The LED package 1 is mounted on, e.g., a mounting board and the LED chip 3 is electrically connected to the mounting board. That is, a pair of feed patterns formed on the mounting board is electrically connected to the filled portions 23A and 23B of the LED package 1 via solder paste. When voltage required for driving the LED chip 3 is applied to the feed patterns, the voltage is then applied to the LED chip 3 via the filled portions 23A, 23B, the wiring patterns 22A, 22B, the bumps 32a, 32b and the electrodes 31a, 31b. The LED chip 3 emits light when an electrical current flows therethrough due to application of the voltage, and light exits outward through the sealing resin 4A. Heat generated in the LED chip 3 is transmitted to the filled portions 23A and 23B via the electrodes 31a, 31b, the bumps 32a, 32b and the wiring patterns 22A, 22B, and is dissipated to the mounting board.

### EFFECTS OF THE FIRST EMBODIMENT

The first embodiment achieves the following effects.

(a) It is the single-sided printed circuit board in which a pair of wiring patterns is formed on a surface of a resin film so as to have a distance as small as possible and through-holes provided at positions corresponding thereto so as to penetrate through the resin film are filled with metal filled portions which are in contact with the wiring patterns and are also exposed on a back surface of the resin film, thereby allowing flip-chip mounting. In addition, since the area of the filled portion is larger than that of the mounting region and is also not less than 50% of the area of the wiring pattern, heat dissipation area of the filled portion is increased, leading to satisfactory heat dissipation.

(b) It is possible to enhance general versatility as a light-emitting element mounting substrate, and as a result, it is possible to provide an LED package of which rate per unit luminosity is cheap.

(c) Regarding heat dissipation, conduction, convection and radiation of heat can be controlled by adjusting a thickness, an area and a position of mainly the wiring pattern or the filled portion.

### Second Embodiment

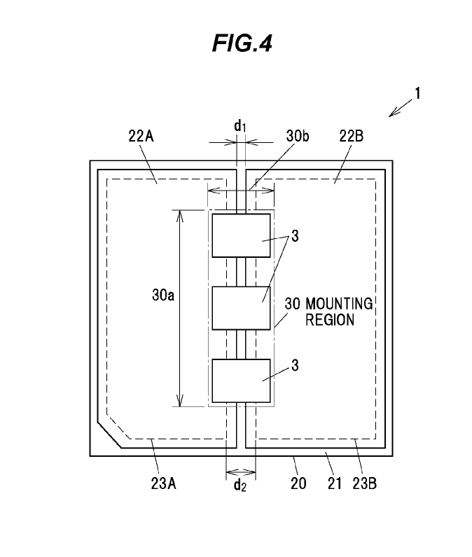

FIG. 4 shows an LED package in a second embodiment of the invention. It should be noted that, FIG. 4 is a plan view showing the LED package without sealing resin and reflective layer. In the second embodiment, it is not necessary to provide a reflective layer.

While one LED chip 3 is mounted on the light-emitting element mounting substrate 2 in the first embodiment, plural (e.g., three) LED chips 3 are mounted in the LED package 1 in the second embodiment.

The mounting region 30 in the second embodiment is a region which includes three LED chips 3. The pair of wiring patterns 22A and 22B have the first distance d1 not more than a length (e.g., 0.3 mm) of the side 30b of the mounting region 30 in the range of not less than a length (e.g., 1.2 mm) of the side 30a of the mounting region 30.

The pair of filled portions 23A and 23B have the second distance d2 not more than a length (e.g., 0.3 mm) of the side 30b of the mounting region 30 in the range of not less than a length (e.g., 1.2 mm) of the side 30a of the mounting region 30.

### Third Embodiment

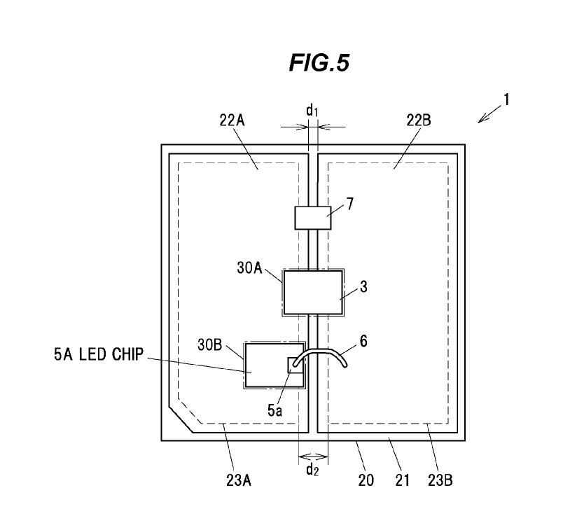

FIG. 5 shows an LED package in a third embodiment of the invention. It should be noted that, FIG. 5 is a plan view showing the LED package without sealing resin and reflective layer. In the third embodiment, it is not necessary to provide a reflective layer.

While only the LED chip(s) 3 is/are mounted in one mounting region 30 in the first and second embodiments, the LED chip(s) 3 as well as another electronic component are mounted in plural mounting regions 30A and 30B in the third embodiment.

That is, in the LED package 1 of the third embodiment, the mounting region 30A is provided on the wiring patterns 22A and 22B in a bridging manner, and the mounting region 30B is provided only on the wiring pattern 22A. This LED package 1 is configured such that the same LED chip 3 as the first and second embodiments is mounted on the mounting region 30A, an LED chip 5A is mounted in the other mounting region 30B and a Zener diode 7 as an electrostatic breakdown preventing element is mounted on the pair of the wiring patterns 22A and 22B in a bridging manner.

The LED chip 5A is a type which has one electrode (not shown) on a bottom surface and another electrode 5a on an upper surface. The electrode of the LED chip 5A on the bottom surface is bonded to the wiring pattern 22A by a bump or a conductive adhesive and the electrode 5a on the upper surface is electrically connected to the other wiring pattern 22B by a bonding wire 6. From the viewpoint of heat dissipation, it is further preferable that the mounting region 30B and the LED chip 5A be arranged within a horizontal projection plane of the filled portion 23A.

### Fourth Embodiment

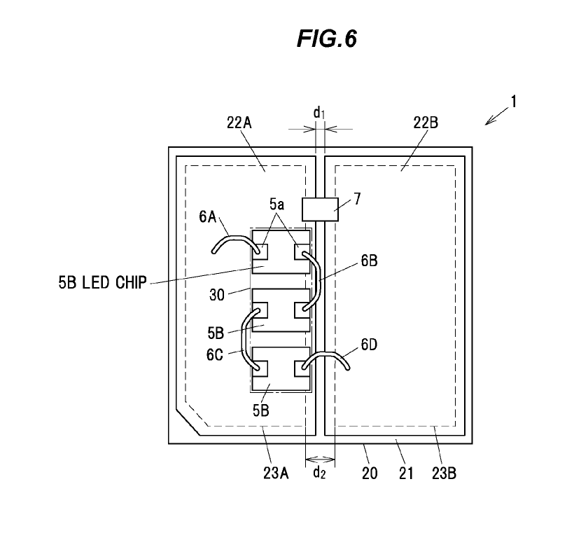

FIG. 6 shows an LED package in a fourth embodiment of the invention. It should be noted that, FIG. 6 is a plan view showing the LED package without sealing resin and reflective layer. In the fourth embodiment, it is not necessary to provide a reflective layer.

While one LED chip 3 is mounted on the wiring patterns 22A and 22B in a bridging manner in the first embodiment, plural (e.g., three) LED chips 5B are mounted on the wiring pattern 22A in the LED package 1 in the fourth embodiment.

In the fourth embodiment, the mounting region 30 is provided on the wiring pattern 22A so as to include the three LED chips 5B. This LED package 1 is configured such that the three LED chips 5B are mounted in the mounting region 30 and the Zener diode 7 as an electrostatic breakdown preventing element is mounted on the pair of the wiring patterns 22A and 22B in a bridging manner.

The LED chip 5B has two electrodes 5a on the upper surface thereof. A bottom surface of the LED chip 5B is bonded to the wiring pattern 22A by an adhesive such as silicone resin. Two of the three LED chips 5B located on both sides are connected to the wiring patterns 22A and 22B at one of the electrodes 5a via bonding wires 6A and 6D, respectively. Between the three LED chips 5B, the electrodes 5a are connected to each other by bonding wires 6B and 6C. From the viewpoint of heat dissipation, it is further preferable that the mounting region 30 and the LED chip 5B be arranged within a horizontal projection plane of the filled portion 23A.

### Fifth Embodiment

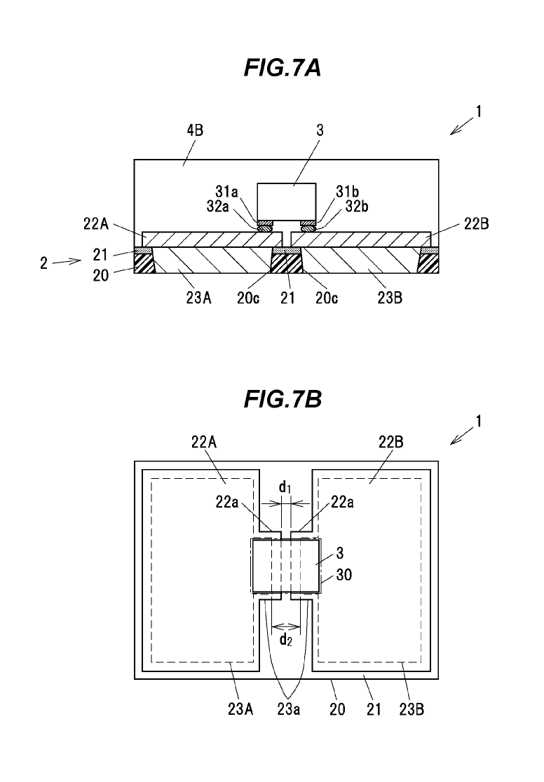

FIG. 7A is a cross sectional view showing an LED package in a fifth embodiment of the invention and FIG. 7B is a plan view showing the LED package of FIG. 7A without sealing resin and reflective layer. In the fifth embodiment, it is not necessary to provide a reflective layer.

While the wiring patterns 22A and 22B have a rectangular shape in the first embodiment, the wiring patterns 22A and 22B are formed in a shape of a rectangle with a protrusion and the filled portions 23A and 23B are also formed in the same shape in the fifth embodiment.

The wiring patterns 22A and 22B each have a convex portion 22a at a position having the first distance d1. The distance d1 between the convex portions 22a is the same as that in the first embodiment. The filled portions 23A and 23B each have a convex portion 23a at a position having the second distance d2. The first distance d1 and the second distance d2 are the same as those in the first embodiment.

According to the fifth embodiment, a length of a portion having the second distance d2 between the filled portions 23A and 23B is short since the convexes of the wiring patterns 22A, 22B and the filled portions 23A, 23B are formed immediately under the LED chip 3 as shown in FIG. 7A, which facilitates to ensure mechanical strength of the portion having the second distance d2, and it is thus easy to form, e.g., not more than 0.20 mm of the second distance d2 between the filled portions 23A and 23B.

In addition, by reducing the distance d2 between the filled portions 23A and 23B, it is possible to reduce the area of the resin film 20 which is a member with a low thermal conductivity located immediately under the LED chip 3 and the areas of the filled portions 23A and 23B can be increased by the reduced area. Therefore, heat conduction capacity in the vicinity of the LED chip 3 can be improved.

In addition, a sealing resin 4B in the fifth embodiment has a block-rectangular shape, unlike the spherical shape in the first embodiment. Since the upper surface of the sealing resin 4B is flat, it is possible to mount by vacuum suction.

The shape of the convex portions 22a and 23a is not limited to the shape shown in FIG. 7B and may be in a multi-step shape, and also, plural convex portions 22a and 23a may be provided. This allows to expect an effect of improving design freedom for arranging electrodes on the LED chip 3.

### Sixth Embodiment

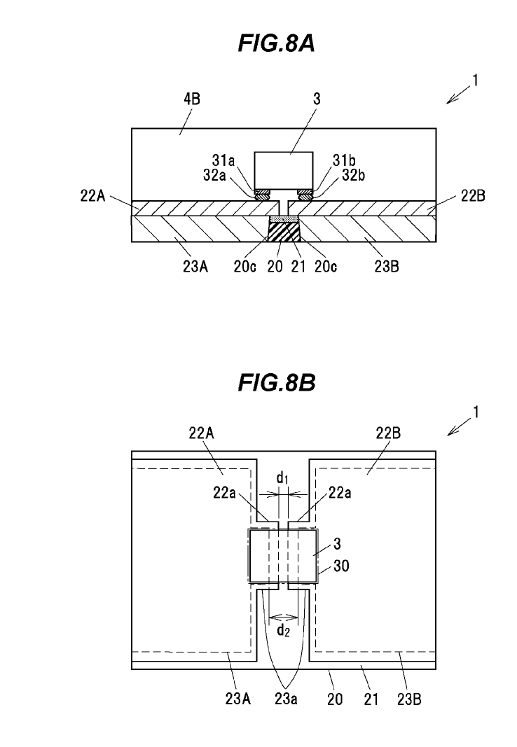

FIG. 8A is a cross sectional view showing an LED package in a sixth embodiment of the invention and FIG. 8B is a plan view showing the LED package of FIG. 8A without sealing resin and reflective layer. In the sixth embodiment, it is not necessary to provide a reflective layer.

The LED package 1 in the sixth embodiment is based on the fifth embodiment and is configured such that outer edges of the wiring patterns 22A, 22B and the filled portions 23A, 23B substantially coincide with the outline of the LED package 1. This facilitates to check an outer appearance of solder fillet after the LED package 1 is mounted on a mounting board by solder reflow. In addition, since the wiring patterns 22A and 22B and portions of the filled portions 23A and 23B are partially exposed, improvement in heat dissipation is expected.

### Seventh Embodiment

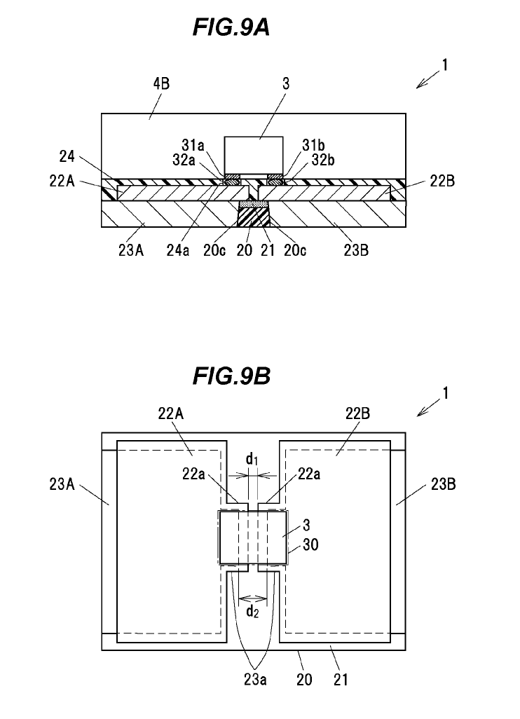

FIG. 9A is a cross sectional view showing an LED package in a seventh embodiment of the invention and FIG. 9B is a plan view showing the LED package of FIG. 9A without sealing resin and reflective layer. In the seventh embodiment, it is not necessary to provide a reflective layer.

The LED package 1 in the seventh embodiment is based on the sixth embodiment and is configured such that the pair of wiring patterns 22A and 22B is formed partially smaller than the filled portions 23A and 23B so that portions of the filled portions 23A and 23B are seen from the wiring pattern side. The process sequence, in which the filled portions 23A and 23B are formed first and the wiring patterns 22A and 22B are subsequently formed, allows such a shape to be formed. This shape improves adhesion of resins such as the reflective layer 24 which is provided on the wiring patterns 22A and 22B side. Especially, a significant effect is expected when the wiring patterns 22A and 22B are formed to have a complex outer shape or to have an etched cross section in an inversely tapered shape.

### Eighth Embodiment

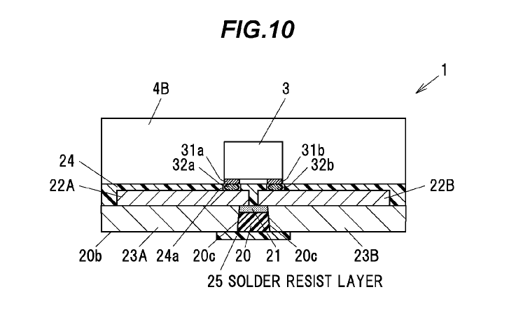

FIG. 10 is a cross sectional view showing an LED package in an eighth embodiment of the invention. In the eighth embodiment, it is not necessary to provide a reflective layer.

The LED package 1 in the eighth embodiment is based on the seventh embodiment and is configured such that a solder resist layer 25 is formed on the back surface 20b of the light-emitting element mounting substrate 2. The solder resist layer 25 is to prevent a solder bridge from occurring on the filled portions 23A and 23B side when conducting the solder reflow mounting. It is possible to form the solder resist layer 25 by screen printing a general liquid resist. It is obvious that the shape of the solder resist layer 25 can be freely designed among an I-shape, an H-shape and a square shape surrounding the outline of the package, etc.

### Ninth Embodiment

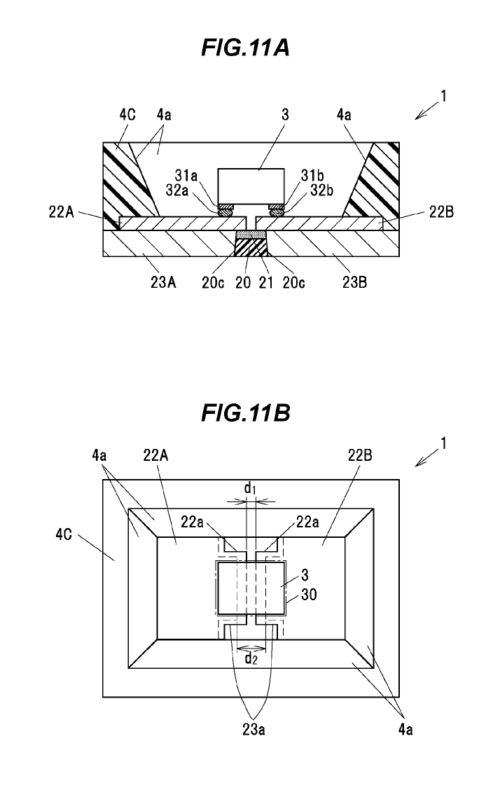

FIG. 11A is a cross sectional view showing an LED package in a ninth embodiment of the invention. FIG. 11B is a plan view showing the LED package of FIG. 11A without sealing resin and reflective layer. It should be noted that, a reflective layer may be provided on the wiring patterns 22A and 22B.

The LED package 1 in the ninth embodiment is based on the eighth embodiment and is configured such that a sealing resin 4C having an inclined surface 4a for reflecting light from the LED chip 3 so as to function as a reflector is formed on the wiring patterns 22A and 22B side by molding a mold resin. Such a mold resin includes CEL-W-7005 (manufactured by Hitachi Chemical Co., Ltd.), etc.

### Tenth Embodiment

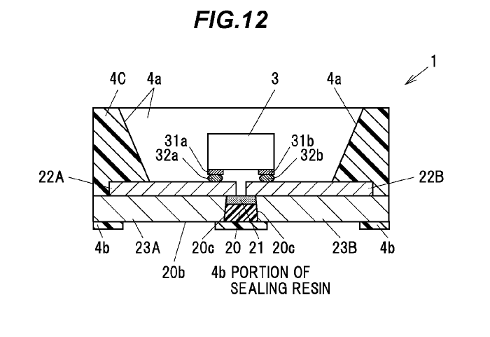

FIG. 12 is a cross sectional view showing an LED package in a tenth embodiment of the invention. It should be noted that, a reflective layer may be provided on the wiring patterns 22A and 22B.

The LED package 1 in the tenth embodiment is based on the ninth embodiment and is configured such that the sealing resin 4C functioning as a reflector partially wraps under the edge of the back surface 20b of the resin film 20. It is desirable that the sealing resins 4C and 4b be partially or entirely integrated by punching one or more through-holes on the outer periphery of the package so that the mold resin also wraps around the filled portions 23A and 23B. This increases mechanical strength of the LED package 1. In addition, when the wiring patterns 22A and 22B are formed to have a complex outer shape or to have an etched cross section in an inversely tapered shape, an effect of making the resin sealing less likely to be separated is expected.

It should be noted that the present invention is not intended to be limited to the embodiments, and the various kinds of modifications can be implemented without departing from the gist of the invention. For example, a heat sink may be connected to the filled portions 23A and 23B via an insulation layer. It is desirable to use an insulation layer with high heat dissipation. In this case, voltage is applied to the LED chip 3 only via the wiring patterns 22A and 22B without passing through the filled portions 23A and 23B.

Evaluation of Heat Dissipation

In order to confirm hear dissipation of the printed circuit board of the invention, a test was conducted in a mounting form similar to FIG. 6. As for a configuration of the printed circuit board in a thickness direction, Upilex S (trade name of Ube Industries, Ltd.) having a thickness of 50 μm was used as the resin film 20, 12 μm of Tomoegawa X (trade name of Tomoegawa Co., Ltd) as the adhesive 21 was laminated thereon, and a 35 μm-thick copper foil was used as the wiring patterns 22A and 22B. Only the pattern on 22B side in FIG. 6 was used as a wiring pattern of the printed circuit board for evaluation. Firstly, a printed circuit board A is configured such that the resin film 20 with a planar size of 2.2×1.6 mm, the pattern 22B of 1.6×1.3 mm and the filled portion 23B of 1.2×1.0 mm are arranged so that the respective centers are located at substantially the same position. In addition, the thickness of the filled portion 23B is 60 μm, and 0.5 μm of nickel plating and 0.5 μm of gold plating are applied to the surfaces of the filled portion 23B and the wiring pattern 22B. A printed circuit board B having the same structure and size but not having the filled portion 23B and through-hole was used for comparison purpose. Then, the printed circuit boards A and B were fixed to a TO-46 stem using Au—Sn paste, a two-wire type LED chip of 0.5 mm square (manufactured by Hitachi Cable Ltd.) was die-bonded to each pattern at about the center by using silver paste, and the TO-46 stem and the LED chip were connected by a gold wire. Additionally, the same LED chip was die-bonded to the TO-46 stem by silver paste and was connected to the TO-46 stem by a gold wire for the comparison purpose.

Thermal resistance and temperature rise in the LED chip were estimated by a transient thermal resistance measuring method (ΔVF method) using the three types of samples. As a result, a temperature rise ΔTj in the LED chip just before being affected by the temperature rise of the TO-46 stem was substantially the same in the LED chip directly wire-bonded to the TO-46 stem and the printed circuit board A having the filled portion, which is about 20° C. On the other hand, ΔTj of the printed circuit board B without filled portion was about 40° C. When expressed in terms of a thermal resistance Rth from the sample to the TO-46 stem, Rth of the LED directly die-bonded to the TO-46 stem and that of the printed circuit board A were about 60° C./W while the Rth of the printed circuit board B without filled portion was about 140° C./W. This shows that the printed circuit board A having the filled portion transmits heat to the TO-46 stem extremely efficiently.

What is claimed is:

1. A light-emitting element mounting substrate, comprising:
an insulative substrate comprising a single-sided printed circuit board;
a pair of wiring patterns formed on one surface of the substrate, the wiring patterns being separated with a first distance;
a pair of through-holes penetrating through the substrate in a thickness direction, the through-holes being separated with a second distance; and
a pair of filled portions comprising a metal filled in the pair of through-holes to contact the pair of wiring patterns and to be exposed on a surface of the substrate opposite to the one surface,
wherein each of the pair of filled portions has a horizontal projected area of not less than 50% of an area of each the pair of wiring patterns.

2. The light-emitting element mounting substrate according to claim 1, wherein the insulative substrate has such flexibility that no crack occurs even when being bent at a radius of 50 mm.

3. The light-emitting element mounting substrate according to claim 1, wherein the pair of wiring patterns each has an area of not less than 0.1 mm²,
wherein the first distance is formed on the one surface of the substrate so that the distance is not less than 1.5 times the thickness of wiring on a surface of the wiring pattern over a range of not less than 0.3 mm, and
wherein the second distance is provided on the substrate so that the distance is not more than 0.2 mm on the one surface side of the substrate over a range of not less than 0.3 mm.

4. The light-emitting element mounting substrate according to claim 1, wherein the pair of wiring patterns is formed of copper or copper alloy, and
wherein the pair of filled portions comprises copper or copper alloy that is filled in the through-holes from the one surface side so as to be half the thickness of the substrate.

5. The light-emitting element mounting substrate according to claim 1, wherein the pair of wiring patterns and the pair of filled portions both have a thermal conductivity of not less than 350 W/mk.

6. The light-emitting element mounting substrate according to claim 1, wherein the pair of wiring patterns each comprises a convex portion at a portion having the first distance, and
wherein the pair of filled portions each comprise a convex portion at a portion having the second distance that is substantially the same position as the convex portion of the pair of wiring patterns.

7. The light-emitting element mounting substrate according to claim 1, wherein the one surface side of the substrate including the pair of wiring patterns comprises a reflective layer that has an initial reflectance of not less than 80% within a wavelength range of 450 to 700 nm in measurement by a spectrophotometer using white color of barium sulfate (BaSO₄) as a criterion.

8. The light-emitting element mounting substrate according to claim 1, wherein the side opposite to the one surface of the substrate comprises a solder resist layer.

9. An LED package, comprising:
an LED chip as the light-emitting element mounted on the pair of wiring patterns of the light-emitting element mounting substrate according to claim 1 in a bridging manner or mounted on an upper surface of one of the wiring patterns, the LED chip being electrically connected to the wiring pattern(s); and
a sealing resin that seals the LED chip.
